(19) United States
(12) Patent Application Publication
(10) Pub. No.: US 2008/0299740 A1
(43) Pub. Date: Dec. 4, 2008

(54) METHOD FOR FORMING STI STRUCTURE

(75) Inventors: Hui-Ying Tsai, Hsinchu (TW); Cheng-Ming Yih, Hsinchu (TW)

Correspondence Address: J C PATENTS, INC., 4 VENTURE, SUITE 250, IRVINE, CA, 92618, US

(73) Assignee: MACRONIX INTERNATIONAL CO., LTD., Hsinchu (TW)

(21) Appl. No.: 11/754,764

(22) Filed: May 29, 2007

(51) Int. Cl. H01L 21/762

(52) U.S. Cl. 438/425; 257/E21.55; 257/E21.267; 257/E21.284

(57) ABSTRACT

A method for forming a shallow trench isolation (STI) structure is described. A patterned mask layer is formed on a substrate, having a trench-like opening therein exposing a portion of the substrate. A thermal oxidation process is performed to the substrate. An anisotropic etching process is performed using the patterned mask layer as a mask to form a trench in the substrate, and then the trench is filled with an insulating material.

### BACKGROUND OF THE INVENTION

1. Field of the Invention

This invention relates to a semiconductor process, and more particularly, to a method for forming a shallow trench isolation (STI) structure.

2. Description of the Related Art

After the semiconductor process advances into deep sub-micron generations, the device isolation structure adopted mostly is the STI structure. As compared with the conventional field oxide (FOX) isolation structure formed with local oxidation of Si (LOCOS), the STI structure takes a smaller lateral area, provides a better isolation effect and is easier to control in the dimension.

In a typical STI process, a patterned SiN layer with a trench-like opening therein is formed on a substrate as a hard mask layer, anisotropic etching is performed using the patterned SiN layer as an etching mask to form a trench in the substrate, and then the trench is filled with an insulating material to form an STI structure. The patterned SiN layer is removed after the STI structure is filled.

However, since the lattice structure of the substrate near the top corners of the trench is damaged in the etching process for forming the patterned SiN layer and in the anisotropic etching for forming the trench in the substrate, much dislocation occurs in the substrate near the top corners of the trench. Therefore, the standby current of the device is increased lowering the device performance.

### SUMMARY OF THE INVENTION

In view of the foregoing, this invention provides a method for forming an STI structure, which can reduce the stress at the top corner of the trench of the STI structure so that dislocation is inhibited thereat and the standby current is decreased.

The method for forming an STI structure of this invention is described below. A patterned mask layer is formed on a substrate, having a trench-like opening therein exposing a portion of the substrate. A thermal oxidation process is performed to the substrate. An anisotropic etching process is performed using the patterned mask layer as a mask to form a trench in the substrate, and then the trench is filled with an insulating material.

In some embodiments, an insulating spacer is further formed on the sidewalls of the trench-like opening after the thermal oxidation process but before the anisotropic etching process, so as to protect the substrate at the top corners of the trench of the STI structure formed later. Moreover, the thermal oxidation process may include an in-situ steam generation (ISSG) oxidation process that may be a rapid thermal process (RTP).

Since a thermal oxidation process is performed to the substrate before the trench is formed in the substrate, the stress in the portions of the substrate corresponding to the top corners of the later-formed trench, which is caused by the patterning of the mask layer, can be reduced. Therefore, less dislocation occurs in subsequent steps, so that the standby current of the device is decreased and the device performance is improved because of the decreased standby current.

It is to be understood that both of the foregoing general description and the following detailed description are exemplary, and are intended to provide further explanation of the invention as claimed.

### BRIEF DESCRIPTION OF THE DRAWINGS

FIGS. 1A-1D illustrate a process flow of a method for forming an STI structure according to a first embodiment of this invention.

FIGS. 2A-2C illustrate a process flow of a method for forming an STI structure according to a second embodiment of this invention.

### DESCRIPTION OF THE PREFERRED EMBODIMENTS

This invention will be further explained with the following embodiments, which are not intended to restrict the scope of this invention. For example, an SiN liner layer may be further formed in the trench of the STI structure to further decrease the stress.

### First Embodiment

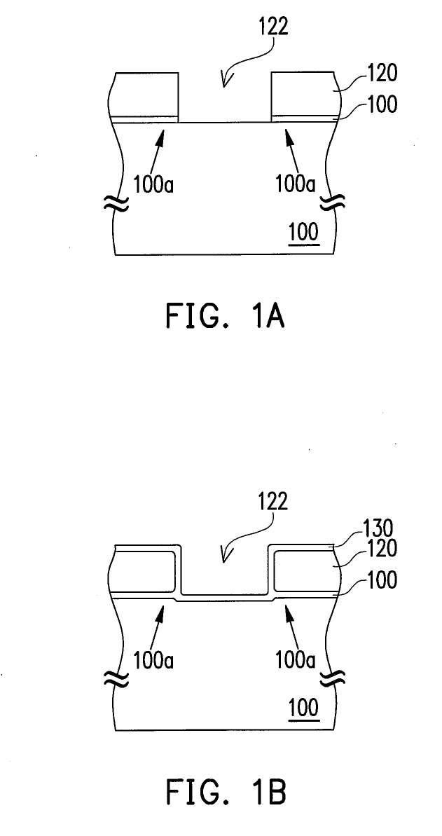

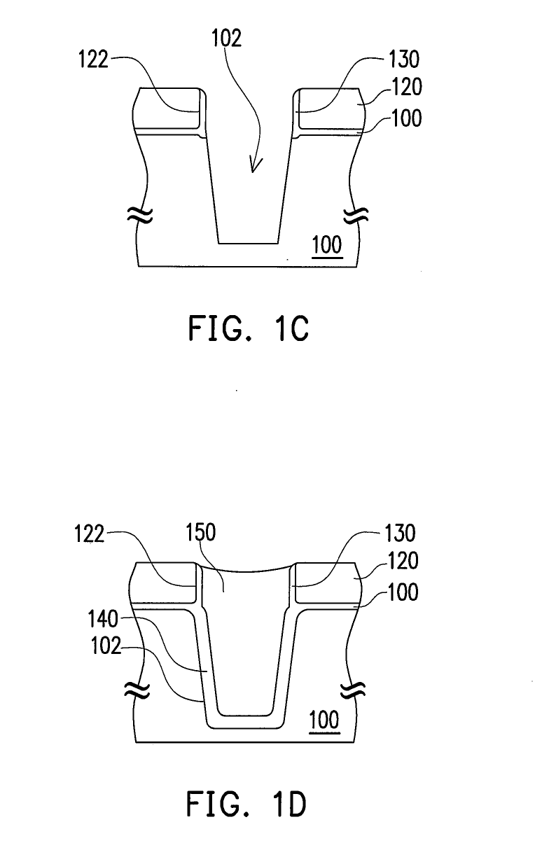

FIGS. 1A-1D illustrate a process flow of a method for forming an STI structure according to the first embodiment of this invention.

Referring to FIG. 1A, a substrate 100 is provided, possibly being a lightly P-doped single-crystal silicon substrate. A patterned mask layer 120, which may include silicon nitride (SiN) formed with LPCVD, is then formed on the substrate 100, having therein a trench-like opening 122 the exposes a portion of the substrate 100. The patterned mask layer 120 may be formed by depositing a layer of a mask material all over the substrate 100 and then patterning the same with lithography and etching. In addition, pad oxide (SiO₂) or pad oxynitride (SiON) 110 may be formed on the substrate 100 as a buffer layer before the mask layer 120 is formed. Because of the etching to the mask material, the portions 100a of the substrate 100 near the edges of the patterned mask layer 120, which correspond to the top corners of the trench formed later, are damaged in the lattice structure to cause a stress.

Referring to FIG. 1B, a thermal oxidation process is conducted to the substrate 100 to form an oxide layer 130 on the exposed surface of the substrate 100 and, in some cases where the oxidation effect is strong, also on the surface of the patterned mask layer 120. The thermal oxidation process may include an in-situ steam generation (ISSG) oxidation process, which may be a rapid thermal process (RTP) conducted at 700-1200° C. for 30-300 seconds, preferably at 950-1100° C. for 120-180 seconds, with in-situ steam generation. Since a high temperature has to be set for the thermal oxidation, the lattice structure of the portions 100a of the substrate 100 is repaired so that less dislocation occurs in subsequent steps.

Referring to FIG. 1C, an anisotropic etching process is performed using the patterned mask layer 120 as an etching mask to form a trench 102 in the substrate 100. When the oxide layer 130 is formed also on the sidewalls of the opening 122, the portions of the oxide layer 130 on the sidewalls of the opening 122 are also a part of the etching mask.

Referring to FIG. 1D, liner oxide 140 is then formed on the surface of the trench 102, possibly through furnace oxidation that may be conducted at 700-1200° C., preferably 950-1100° C. The liner oxide 140 may alternatively be formed with an ISSG approach, which may be conducted at 700-1200° C. for 30-300 seconds, preferably at 950-1100° C. for 120-180 seconds. After that, an insulating material 150 is filled into the trench 102 to form a shallow trench isolation (STI) structure. The trench 102 may be filled by depositing the insulating material all over the substrate 100 and then removing portions thereof outside the trench 102. The insulating material 150 may include silicon dioxide (SiO₂). It is noted that the liner oxide 140 is formed to be a buffer layer between the substrate 100 and the insulating material 150, and the process of forming the liner oxide 140 helps to repair the lattice structure of the substrate 100 around the trench 102 that is damaged in the anisotropic etching process.

### Second Embodiment

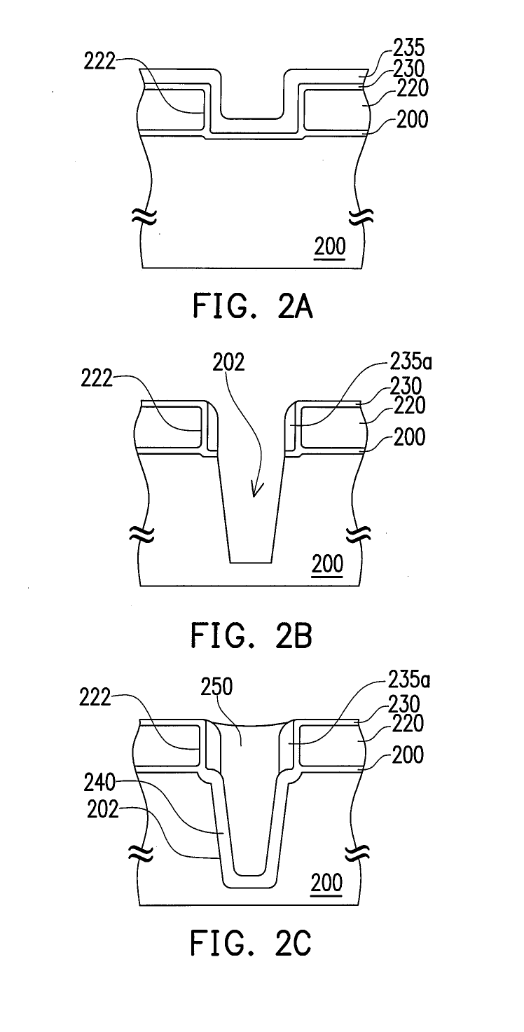

FIGS. 2A-2C illustrate a process flow of a method for forming an STI structure according to the second embodiment of this invention.

Referring to FIG. 2A, a structure including a substrate 200, pad oxide (SiO₂) or pad oxynitride (SiON) 210, a patterned mask layer 220 with a trench-like opening 222 therein and a thermal oxide layer 230 may be formed as in the first embodiment, wherein the material of each part may be the same as above. Then, a substantially conformal insulating layer 235 is formed over the substrate 200. The material of the insulating layer 235 may be high-temperature oxide (HTO) that is formed through CVD at about 600-1100° C., preferably about 700-900° C.

Referring to FIG. 2B, an anisotropic etching process is performed to the substrate 200. A portion of the insulating layer 235 is firstly removed to form an insulating spacer 235a on the sidewalls of the opening 222, while the etching recipe set at this stage preferably has a higher selectivity to the material of the insulating layer 235. The anisotropic etching process is continued, with the patterned mask layer 220 and the insulating spacer 235a as a mask and with an etching recipe having a higher selectivity to the material of the substrate 200, to form a trench 202 in the substrate 200. Since the insulating spacer 235a can protect the substrate 200 at the top corners of the trench 202, less stress is accumulated thereat.

Referring to FIG. 2C, liner oxide 240 is then formed on the surface of the trench 202, possibly through furnace oxidation that may be conducted at 700-1200° C., preferably 950-1100° C. The liner oxide 240 may alternatively be formed with an ISSG approach, which may be conducted at 700-1200° C. for 30-300 seconds, preferably at 950-1100° C. for 120-180 seconds. After that, an insulating material 250 is filled into the trench 202 to form an STI structure. The trench 202 may be filled by depositing the insulating material all over the substrate 200 and then removing the portions thereof outside the trench 202. The insulating material 250 may include silicon dioxide. It is noted that the liner oxide 240 is formed to be a buffer layer between the substrate 200 and the insulating material 250, and the process of forming the liner oxide 240 helps to repair the lattice structure of the substrate 200 around the trench 202 that is damaged in the anisotropic etching process.

Since a thermal oxidation process is performed to the substrate before the trench is formed in the substrate, the stress in the portions of the substrate corresponding to the top corners of the later-formed trench, which is caused by the patterning of the mask layer, can be reduced. Therefore, less dislocation occurs in subsequent steps, so that the standby current of the device is decreased and the device performance is improved because of the decreased standby current.

It will be apparent to those skilled in the art that various modifications and variations can be made to the structure of the present invention without departing from the scope or spirit of the invention. In view of the foregoing, it is intended that the present invention covers modifications and variations of this invention provided they fall within the scope of the following claims and their equivalents.

1. A method for forming a shallow trench isolation (STI) structure, comprising:
forming a patterned mask layer on a substrate, the patterned mask layer having a trench-like opening therein exposing a portion of the substrate;
performing a first thermal oxidation process to the substrate after the patterned mask layer is formed;
performing an anisotropic etching process with the patterned mask layer as a mask to form a trench in the substrate, after the first thermal oxidation process is performed; and
filling the trench with an insulating material.

2. The method of claim 1, wherein the first thermal oxidation process comprises an in-situ steam generation (ISSG) oxidation process.

3. The method of claim 2, wherein the ISSG oxidation process is a rapid thermal process (RTP).

4. The method of claim 3, wherein the rapid thermal process (RTP) is conducted at 700-1200° C. for 30-300 seconds.

5. The method of claim 4, wherein the rapid thermal process (RTP) is conducted at 950-1100° C. for 120-180 seconds.

6. The method of claim 1, wherein the patterned mask layer comprises SIN.

7. The method of claim 6, further comprising forming pad oxide or pad oxynitride on the substrate before the patterned mask layer is formed.

8. The method of claim 1, further comprising forming liner oxide on a surface of the trench before the trench is filled with the insulating material.

9. The method of claim 8, wherein the liner oxide is formed with a second thermal oxidation process.

10. The method of claim 9, wherein the second thermal oxidation process comprises an in-situ steam generation (ISSG) oxidation process.

11. A method for forming a shallow trench isolation (STI) structure, comprising:
forming a patterned mask layer on a substrate, the patterned mask layer having a french-like opening therein exposing a portion of the substrate;
performing a first thermal oxidation process to the substrate after the patterned mask layer is formed;
forming an insulating spacer on a sidewall of the trench-like opening, after the first thermal oxidation process is performed;
performing an anisotropic etching process with the patterned mask layer and the insulating spacer as a mask to form a trench in the substrate; and
filling the french with an insulating material.

12. The method of claim 11, wherein the first thermal oxidation process comprises an in-situ steam generation (ISSG) oxidation process.

13. The method of claim 12, wherein the ISSG oxidation process is a rapid thermal process (RTP).

14. The method of claim 13, wherein the rapid thermal process (RTP) is conducted at 700-1200° C. for 30-300 seconds.

15. The method of claim 14, wherein the rapid thermal process (RTP) is conducted at 950-1100° C. for 120-180 seconds.

16. The method of claim 11, wherein forming the insulating spacer comprises:
forming a substantially conformal insulating layer over the substrate; and
anisotropically etching the insulating layer to form the insulating spacer.

17. The method of claim 16, wherein the insulating layer comprises high-temperature oxide (HTO) formed with CVD at 600-1100° C.

18. The method of claim 17, wherein the insulating layer comprises high-temperature oxide (HTO) formed with CVD at 700-900° C.

19. The method of claim 11, wherein the patterned mask layer comprises SiN.

20. The method of claim 19, further comprising forming pad oxide or pad oxynitride on the substrate before the patterned mask layer is formed.

21. The method of claim 11, further comprising forming liner oxide on a surface of the trench before the trench is filled with the insulating material.

22. The method of claim 21, wherein the liner oxide is formed with a second thermal oxidation process.

23. The method of claim 22, wherein the second thermal oxidation process comprises an in-situ steam generation (ISSG) oxidation process.
